(19) United States
(12) Patent Application Publication
(10) Pub. No.: US 2026/0020254 A1
(43) Pub. Date: Jan. 15, 2026

(54) SEMICONDUCTOR CHIP, SEMICONDUCTOR PACKAGE INCLUDING THE SAME, AND METHOD FOR MANUFACTURING THE SAME

(71) Applicant: Samsung Electronics Co., Ltd., Suwon-si (KR)

(72) Inventors: Hyun-Chul Yoon, Suwon-si (KR); ChangSik Yoo, Suwon-si (KR); Kyu-Chang Kang, Suwon-si (KR); Sang-Yun Kim, Suwon-si (KR); Young Seok Park, Suwon-si (KR); Younghun Seo, Suwon-si (KR)

(21) Appl. No.: 19/177,908

(22) Filed: Apr. 14, 2025

(30) Foreign Application Priority Data
Jul. 15, 2024 (KR) 10-2024-0093139

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0652; H01L 25/18; H01L 25/50; H10B 12/315; H10B 12/50; H01L 2224/08145; H01L 2224/80006; H01L 2224/80895; H01L 2224/80896; H01L 2924/1431; H01L 2924/1436; H01L 2924/37001

(57) ABSTRACT

Provided are a semiconductor chip, a semiconductor package including the same, and a method for manufacturing the same. This semiconductor chip includes a first logic die, first memory dies arranged side by side in a first direction on the first logic die, and a first mold layer between the first memory dies. The first memory dies and the first mold layer are in contact with an upper surface of the first logic die, each of the first memory dies includes first memory bank regions arranged side by side in a second direction intersecting the first direction, and the first logic die includes first core regions overlapping the first memory bank regions, respectively, in a third direction that is perpendicular to the first and second directions.

### CROSS-REFERENCE TO RELATED APPLICATIONS

This U.S. non-provisional patent application claims priority under 35 U.S.C. § 119 from Korean Patent Application No. 10-2024-0093139, filed on Jul. 15, 2024, the contents of which are hereby incorporated by reference herein in its entirety.

### TECHNICAL FIELD

The present disclosure herein relates to a semiconductor chip, a semiconductor package including the same, and a method for manufacturing the same.

### BACKGROUND

An integrated circuit chip may be packaged into a semiconductor package to have a suitable form to be installed in an electronic device. In general, in a semiconductor package, a semiconductor die is mounted on a printed circuit board (PCB), and the semiconductor die and the PCB are electrically connected to each other using bonding wires or bumps. With development of the electronics industry, various research has been conducted to improve the reliability and durability of semiconductor packages.

### SUMMARY

The present disclosure provides a highly integrated semiconductor chip and semiconductor package.

The present disclosure also provides a method for manufacturing a semiconductor chip, with which the manufacturing cost can be reduced.

Embodiments of the present disclosure are not limited to the above-mentioned purposes, and other purposes not mentioned would be clearly understood by those skilled in the art from the disclosure below.

An embodiment of the inventive concept provides a semiconductor chip including: a first logic die; first memory dies arranged side by side in a first direction on the first logic die; and a first mold layer between the first memory dies, wherein the first memory dies and the first mold layer are in contact with an upper surface of the first logic die, each of the first memory dies includes first memory bank regions arranged side by side in a second direction intersecting the first direction, and the first logic die includes first core regions overlapping the first memory bank regions, respectively, in a third direction that is perpendicular to the first and second directions.

In an embodiment of the inventive concept, a semiconductor chip includes: a logic die; memory dies arranged side by side in a first direction on the logic die; and a mold layer between the memory dies, wherein the logic die includes: a first substrate; peripheral transistors on the first substrate; a peripheral interlayer insulating layer on the peripheral transistors; and peripheral lines in the peripheral interlayer insulating layer, and each of the memory dies includes: an active pattern extending perpendicular to an upper surface of the first substrate; a word line adjacent to a side surface of the active pattern in the first direction; a bit line under the active pattern; a capacitor on the active pattern opposite the bit line; and a cell interlayer insulating layer on the active pattern, the word line, the bit line, and the capacitor, wherein the mold layer includes a material different from respective materials of the cell interlayer insulating layer and the peripheral interlayer insulating layer.

In an embodiment of the inventive concept, a semiconductor package includes: a buffer die; chip structures stacked on the buffer die; and a first mold layer on the buffer die and the chip structures, wherein each of the chip structures includes: a logic die; memory dies bonded on the logic die and arranged side by side in a first direction between the logic die and the buffer die; a second mold layer between the memory dies; and mold vias extending into the second mold layer, wherein the logic die includes first connection pads at an upper surface thereof, second connection pads at a lower surface thereof that is opposite the upper surface, and through-vias connecting the first connection pads to a first subset of the second connection pads, each of the memory dies includes third connection pads arranged at an upper end thereof and being in contact with a second subset of the second connection pads, the mold vias are in contact with the first connection pads, and a first thickness of the logic die is different from a second thickness of each of the memory dies in a direction that is perpendicular to the upper surface of the logic die.

In an embodiment of the inventive concept, a method for manufacturing a semiconductor chip includes: manufacturing a first wafer comprising first device regions and a separation region between the first device regions, each of the first device regions having a logic die structure; manufacturing a second wafer comprising second device regions having memory bank regions; forming memory dies with the second device regions by sawing the second wafer; bonding the memory dies onto the first device regions; at least partially filling spaces between the memory dies with a first mold layer; and sawing the first wafer and the first mold layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a block diagram illustrating a semiconductor chip according to embodiments of the inventive concept;

FIG. 1B is a perspective view schematically illustrating a semiconductor chip according to embodiments of the inventive concept;

FIGS. 2A and 2B are perspective views schematically illustrating a semiconductor chip according to embodiments of the inventive concept;

FIG. 3 is a cross-sectional view taken along line A-A′ of FIG. 2A according to embodiments of the inventive concept;

FIG. 4 is a plan view of a memory bank region according to embodiments of the inventive concept;

FIG. 5 is an enlarged view of portion PI of FIG. 3 according to embodiments of the inventive concept;

FIG. 6A is a plan view of a first wafer for producing a logic die of an embodiment of the inventive concept;

FIG. 6B is a plan view of a logic die of an embodiment of the inventive concept;

FIG. 7A is a plan view of a second wafer for producing a memory die of an embodiment of the inventive concept;

FIGS. 7B, 7C, and 7D are plan views of memory dies of an embodiment of the inventive concept;

FIGS. 8A, 8B, 8C, 8D, 8E, and 8F are cross-sectional views illustrating a process of manufacturing the semiconductor chip of FIG. 2A;

FIG. 9A is a cross-sectional view of a semiconductor chip according to embodiments of the inventive concept;

FIG. 9B is a cross-sectional view of a semiconductor chip according to embodiments of the inventive concept;

FIG. 10 is a cross-sectional view of a semiconductor chip according to embodiments of the inventive concept;

FIG. 11 is a cross-sectional view of a semiconductor chip according to embodiments of the inventive concept;

FIG. 12A is a cross-sectional view of a semiconductor chip according to embodiments of the inventive concept;

FIG. 12B is a cross-sectional view of a semiconductor chip according to embodiments of the inventive concept;

FIG. 13 is a cross-sectional view of a semiconductor chip according to embodiments of the inventive concept;

FIG. 14 is a cross-sectional view of a semiconductor package according to embodiments of semiconductor package;

FIG. 15 is a cross-sectional view of a semiconductor package according to embodiments of semiconductor package; and

FIG. 16 is a cross-sectional view of a semiconductor package according to embodiments of semiconductor package.

### DETAILED DESCRIPTION

Hereinafter, a semiconductor memory device and a method for manufacturing the same according to embodiments of the inventive concept will be described in detail with reference to the accompanying drawings. Herein, the terms indicating order, such as first, second, etc., are used to distinguish elements having the same/similar functions, and the ordinal numbers may be interchanged according to the order in which the terms are mentioned. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

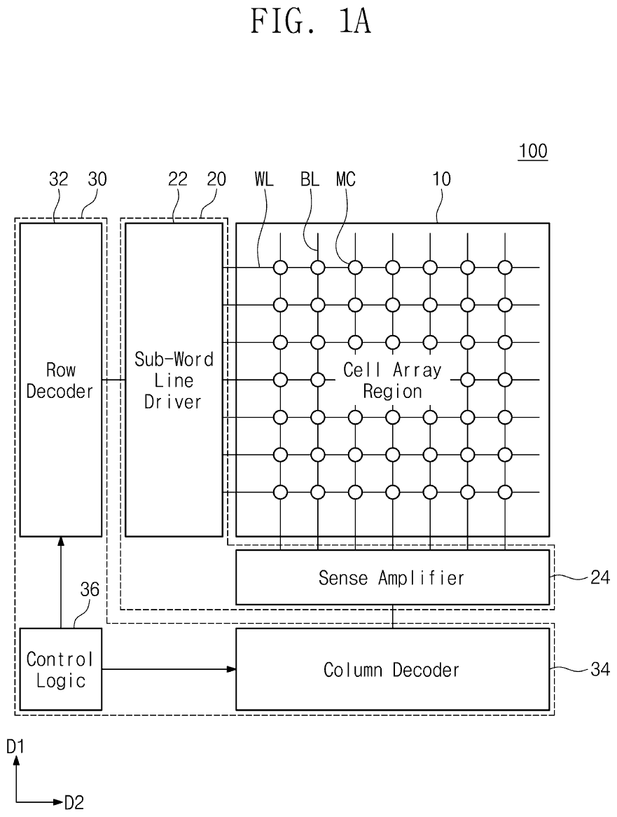

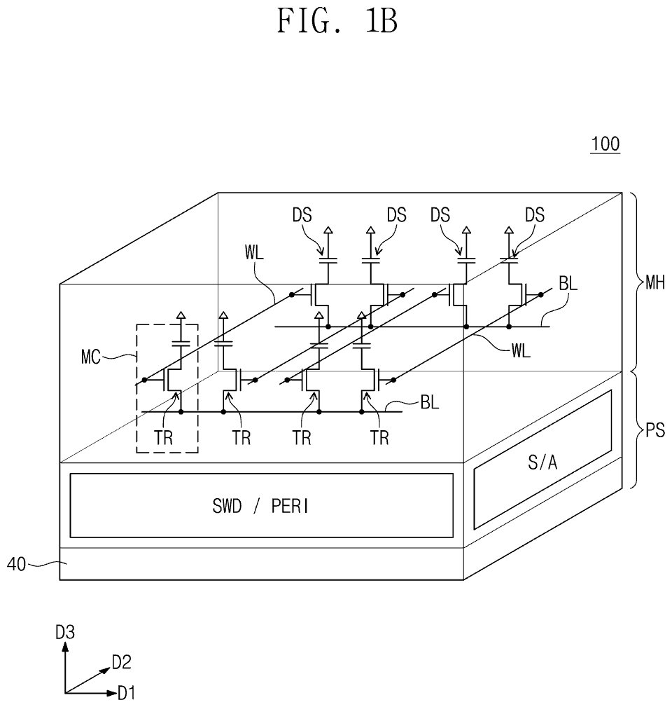

FIG. 1A is a block diagram illustrating a semiconductor chip according to embodiments of the inventive concept.

Referring to FIG. 1A, a semiconductor chip 100 according to the present example may include a cell array region 10, a core region 20, and a peripheral circuit region 30. In the present disclosure, the semiconductor chip 100 may also be referred to as a semiconductor memory device or a chip structure. Word lines WL and bit lines BL intersecting each other may be arranged in the cell array region 10. A plurality of memory cells MC may be two-dimensionally or three-dimensionally arranged in the cell array region 10. Each of the memory cell MC may be connected between the word line WL and the bit line BL intersecting each other.

The core region 20 may be disposed at a periphery of the cell array region 10. A sub-word line driver 22 and a sense amplifier 24 may be arranged in the core region 20. The peripheral circuit region 30 may be disposed at a periphery of the core region 20. A row decoder 32, a column decoder 34, and a control logic 36 may be arranged in the peripheral circuit region 30. Input/output circuits, voltage generation circuits, and fuse circuits may be arranged in the peripheral circuit region 30.

The row decoder 32 may decode an externally input row address signal or refresh address signal. The sub-word line driver 22 may perform a function of selecting a particular word line WL in response to a row address signal or a refresh address signal.

The sense amplifier 24 may sense and amplify a voltage difference between a reference bit line and the bit line BL selected according to an address decoded by the column decoder 34 and output the amplified voltage difference.

The column decoder 34 may provide a data transmission path between the sense amplifier 24 and an external device (e.g., memory controller). The column decoder 34 may decode an externally input column address signal and select any one of the bit lines BL.

The control logic 36 may generate control signals for controlling operations of writing or reading data to or from a memory cell array of the cell array region 10.

The cell array region 10 may correspond to, for example, a page region or mat region of a DRAM device. The page region (or mat region) may be provided in plurality and two-dimensionally arranged along a first direction D1 and a second direction D2, thus forming one memory bank region BK. The memory bank region may be provided in plurality and two-dimensionally arranged along the first direction D1 and the second direction D2. Each one of the memory cells MC may store 1-bit data. The page region may include the memory cells MC in units (or sizes) of pages. The memory bank region BK may include the memory cell MC in units (or sizes) of banks.

One sub-word line driver 22 and one sense amplifier 24 may be connected to one page region. As the page region is provided in plurality, the sub-word line driver 22 and the sense amplifier 24 may also be provided in plurality. When M×N number of the page regions are provided, M×N number of the sub-word line drivers 22 and M×N number of the sense amplifiers 24 may also be provided. One row decoder 32 and one column decoder 34 may be connected to one memory bank region. As the memory bank region is provided in plurality, the row decoder 32 and the column decoder 34 may also be provided in plurality. When K×J number of the memory bank regions are provided, K×J number of the row decoders 32 and K×J number of the column decoders 34 may also be provided. K, J, M, and N may each be a natural number equal to or greater than 2.

FIG. 1B is a perspective view schematically illustrating a semiconductor chip according to embodiments of the inventive concept.

Referring to FIG. 1B, the semiconductor chip 100 may include a logic die PS and a memory die MH. The memory die MH may only have a memory function for storing data and may exclude (i.e., may be free of) logic circuits. The memory die MH may only include the memory cells MC. The logic die PS may have a function of storing data in the memory cells MC of the memory die MH or reading or performing operation/process on stored data, and may include circuits suitable for the function.

The logic die PS may include the core region 20 and the peripheral circuit region 30 of FIG. 1A. The logic die PS may include a first substrate 40. Peripheral transistors and peripheral lines may be arranged on the first substrate 40, thus forming sub-word line driver circuits SWD and sense amplifier circuits S/A of the core region 20 of FIG. 1A and peripheral circuits PERI of the peripheral circuit region 30 of FIG. 1A.

The memory die MH may include the cell array region 10 of FIG. 1A. The memory die MH may include the bit lines BL and the word lines WL and the memory cells MC therebetween. The memory cells MC may be two-dimensionally or three-dimensionally arranged on a plane extending in the first and second directions D1 and D2 intersecting each other. The memory cells MC may each include a selection element TR and a data storage element DS.

The selection element TR may be a field effect transistor (FET). A gate electrode of the transistor may be connected to the word line WL, and drain/source terminals of the transistor may be connected to the bit line BL and the data storage element DS. The word line WL may be parallel with the second direction D2, and the bit line BL may be parallel with the first direction D1. The selection element TR and the data storage element DS may be arranged side by side in a third direction D3 in one memory cell MC.

According to embodiments, the selection element TR of each memory cell MC may be a vertical channel transistor (VCT). The vertical channel transistor may have a structure in which a channel extends in a direction (i.e., third direction D3) perpendicular to an upper surface of the first substrate 40, also referred to herein as a vertical direction. However, an embodiment of the inventive concept is not limited thereto, and the selection element TR may have a form of buried channel array transistor (BCAT), planar transistor, fin field-effect transistor (FinFET), multi-bridge channel FET (MBCFET), or gate all around (GAA) transistor. In another example, the selection element TR and the storage element DS may be arranged side by side along the first direction D1 or the second direction D2, and the word line WL or the bit line BL may extend along the third direction D3 and may be perpendicular to the upper surface of the first substrate 40. Spatially relative terms such as ‘upper,’ ‘upper portion,’ ‘upper surface,’ ‘lower,’ ‘lower portion,’ ‘lower surface,’ ‘side surface,’ ‘over,’ ‘under,’ and the like may be denoted by reference numerals and refer to the drawings, except where otherwise indicated. It will be understood that such spatially relative terms are intended to encompass different orientations of the device in use or operation in addition to the orientation depicted in the figures.

The data storage element DS may be implemented as a capacitor, a magnetic tunnel junction pattern, a variable resistor, or the like. In the present example, a capacitor may be provided as the data storage element DS of each memory cell MC. The memory die MH may have a cell array region structure of DRAM, PRAM, or MRAM according to a type of the data storage element DS. In another example, the memory die MH may have a cell array region structure of VNAND. In this case, the memory die MH may include a stack structure in which electrode layers and inter-electrode insulating layers are alternately stacked, vertical semiconductor patterns penetrating (e.g., extending into or through) the stack structure, and a gate insulating layer interposed between the vertical semiconductor pattern and the stack structure. The gate insulating layer may include a tunnel insulating layer, a storage pattern, and a blocking insulating layer sequentially arranged from a sidewall of the vertical semiconductor pattern.

The logic die PS may also be referred to as a “first die”. The memory die MH may also be referred to as a “second die”. The first die may perform only a first function, and a second die may perform only a second function. Dies included in a semiconductor chip according to an embodiment of the inventive concept may be separately manufactured for each function.

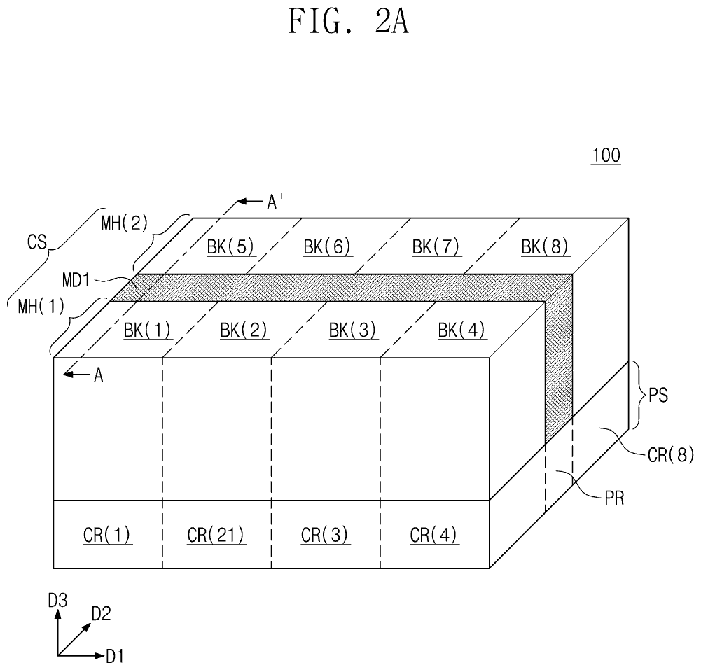

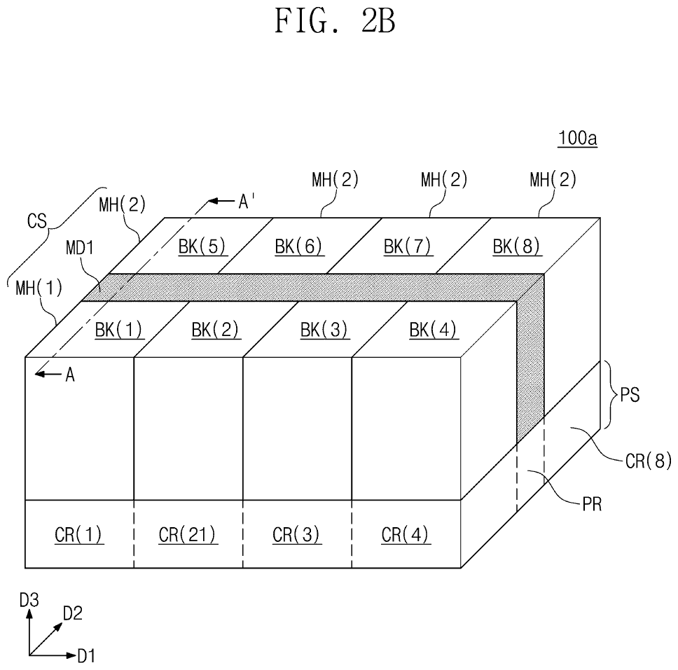

FIGS. 2A and 2B are perspective views schematically illustrating a semiconductor chip according to embodiments of the inventive concept.

Referring to FIG. 2A, the semiconductor chip 100 according to the present example includes the logic die PS and a cell structure CS disposed thereon. The cell structure CS includes memory dies MH and a first mold layer MD1. The logic die PS may include core regions CR and a peripheral circuit region PR. The core regions CR may include first to eighth core regions CR(1) to CR(8) arranged two-dimensionally along the first direction D1 and the second direction D2. The core regions CR(1) to CR(8) may each include the sub-word line driver circuits SWD and the sense amplifier circuits S/A. The first to fourth core regions CR(1) to CR(4) may be arranged side by side along the first direction D1 and located in front of the logic die PS (i.e., in a forward portion shown in the views of FIGS. 2A-2B). The fifth to eighth core regions CR(5) to CR(8) may be arranged side by side along the first direction D1 and located behind the logic die PS (i.e., in a rearward portion shown in the views of FIGS. 2A-2B). The peripheral circuit region PR may be disposed between the first to fourth core regions CR(1) to CR(4) and the fifth to eighth core regions CR(5) to CR(8). Row decoder circuits, column decoder circuits, control logics, input/output circuits, voltage generation circuits, fuse circuits, and the like may be arranged in the peripheral circuit region PR. The logic die PS may exclude (i.e., may be free of) the memory cells MC of FIGS. 1A and 1B having a data storage function.

The memory dies MH may be located on the logic die PS. The memory dies MH may include first and second memory dies MH(1) and MH(2). The first and second memory dies MH(1) and MH(2) may be elongated in the first direction D1 and may be arranged side by side and spaced apart from each other along the second direction D2. The first and second memory dies MH(1) and MH(2) may each include a plurality of memory bank regions BK.

The first memory die MH(1) may include first to fourth memory bank regions BK(1) to BK(4) arranged side by side in the first direction D1. The first to fourth memory bank regions BK(1) to BK(4) may be adjacent to each other. The first to fourth memory bank regions BK(1) to BK(4) may overlap the first to fourth core regions CR(1) to CR(4), respectively, in the vertical direction. Components or layers described with reference to “overlap” in a particular direction may be at least partially obstructed by one another when viewed along a line extending in the particular direction or in a plane perpendicular to the particular direction. The first to fourth memory bank regions BK(1) to BK(4) may be connected in correspondence to the first to fourth core regions CR(1) to CR(4), respectively. The first memory die MH(1) does not include a dummy region overlapping the peripheral circuit region PR.

The second memory die MH(2) may include fifth to eighth memory bank regions BK(5) to BK(8) arranged side by side in the first direction D1. The fifth to eighth memory bank regions BK(5) to BK(8) may be adjacent to each other. The fifth to eighth memory bank regions BK(5) to BK(8) may overlap the fifth to eighth core regions CR(5) to CR(8), respectively, in the vertical direction. The fifth to eighth memory bank regions BK(5) to BK(8) may be connected in correspondence to the fifth to eighth core regions CR(5) to CR(8), respectively. The second memory die MH(2) does not include a dummy region overlapping the peripheral circuit region PR.

The first mold layer MD1 is interposed between the first memory die MH(1) and the second memory die MH(2). The first mold layer MD1 may be connected to the peripheral circuit region PR of the logic die PS. Upper surfaces of the first memory die MH(1) and the second memory die MH(2) may be coplanar with an upper surface of the first mold layer MD1. The first mold layer MD1 may include an insulative resin such as an epoxy molding compound (EMC). The first mold layer MD1 may further include a filler, which may be dispersed in the insulative resin. The filler may include an insulating material such as silica or alumina.

Alternatively, referring to FIG. 2B, a semiconductor chip 100a according to the present example includes the logic die PS and the cell structure CS disposed thereon. The cell structure CS includes the first and second memory dies MH(1) and MH(2) and the first mold layer MD1. A plurality, for example, four of the first memory dies MH(1) may be provided and arranged in a row along the first direction D1. A plurality of, for example, four of the second memory dies MH(2) may be provided and arranged in a row along the first direction D1. The first memory dies MH(1) may each have one memory bank region BK. The second memory dies MH(2) may each have one memory bank region BK. Other structures may be the same as those described with reference to FIG. 2A.

Since the memory dies MH having only a memory function (also referred to herein as dedicated memory dies) are stacked and arranged on the logic die PS having only a logic function (also referred to herein as a dedicated logic die) in the semiconductor chip 100 or 100a according to an embodiment of the inventive concept, a memory capacity of the semiconductor chip 100 or 100a may be increased while reducing a horizontal size thereof.

FIG. 3 is a cross-sectional view taken along line A-A′ of FIG. 2A according to embodiments of the inventive concept.

Referring to FIGS. 2A and 3, the memory dies MH are stacked on the logic die PS. A space between the memory dies MH may be filled with the first mold layer MD1. The logic die PS includes the first substrate 40. The first substrate 40 may be a semiconductor substrate, a silicon on insulator (SOI) substrate, or an insulating substrate. Device isolation patterns 43 may be arranged in the first substrate 40 to define active regions for peripheral transistors PTR1, PTR2, and PTR3. The device isolation patterns 43 may have a single-layer or multi-layer structure of at least one of silicon oxide or silicon nitride.

The logic die PS may include first to third peripheral transistors PTR1 to PTR3, peripheral contact plugs PC1, peripheral lines PI1, and peripheral interlayer insulating layer PL1 arranged on the first substrate 40. The first to third peripheral transistors PTR1 to PRT3 may each have a form of planar transistor, fin field-effect transistor (FinFET), multi-bridge channel FET (MBCFET), gate all around (GAA) transistor, or buried channel array transistor (BCAT). The first to third peripheral transistors PTR1 to PRT3 may each be connected to the peripheral contact plugs PC1 and the peripheral lines PI1. The peripheral interlayer insulating layer PL1 may cover the first to third peripheral transistors PTR1 to PRT3, the peripheral contact plugs PC1, and the peripheral lines PI1. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout. First connection pads CCP1 are arranged at an upper end or surface of the peripheral interlayer insulating layer PL1. The first connection pads CCP1 are connected to the peripheral contact plugs PC1 and the peripheral lines PI1.

The first connection pads CCP1, the peripheral contact plugs PC1, and the peripheral lines PI1 may each include metal such as copper, aluminum, tungsten, titanium, tantalum, titanium nitride, and tantalum nitride. The peripheral interlayer insulating layer PL1 may be formed of a material different from that of the first mold layer MD1. The peripheral interlayer insulating layer PL1 may have a single-layer or multi-layer structure of at least one of silicon oxide, silicon nitride, silicon oxynitride, SiCN, or porous insulator.

In each of the core regions CR, the first peripheral transistors PTR1 and the peripheral contact plugs PCI and the peripheral lines PI1 connected thereto may constitute the sense amplifiers 24 of FIG. 1A. In each of the core regions CR, the second peripheral transistors PTR2 and the peripheral contact plugs PC1 and the peripheral lines PI1 connected thereto may constitute the sub-word line drivers 22 of FIG. 1A. The third peripheral transistors PTR3 and the peripheral contact plugs PC1 and the peripheral lines PI1 connected thereto may be arranged in the peripheral circuit region PR and may constitute the row decoders 32, the column decoders 34, and the control logic circuits 36 of FIG. 1A.

The memory die MH may include first to seventh cell interlayer insulating layers IL1 to IL7 sequentially stacked and bit lines BL, shield lines SHL, word lines WL, back gate lines BGL, and capacitors CAP arranged therein. The first to seventh cell interlayer insulating layers IL1 to IL7 may each be formed of a material different from that of the first mold layer MD1. The first mold layer MD1 may include an insulative resin such as an epoxy molding compound (EMC). The first to seventh cell interlayer insulating layers IL1 to IL7 may each have a single-layer or multi-layer structure of at least one of silicon oxide, silicon nitride, silicon oxynitride, or porous insulator. A second substrate 60 may be disposed on the seventh cell interlayer insulating layer IL7. The second substrate 60 may be formed of a semiconductor material or an insulating material.

First cell lines IT1 and first cell contact plugs CTI may be arranged in the first cell interlayer insulating layer IL1. Second connection pads CCP2 may be arranged at a lower end or surface of the first cell interlayer insulating layer IL1 and may be in contact with the first connection pads CCP1, respectively.

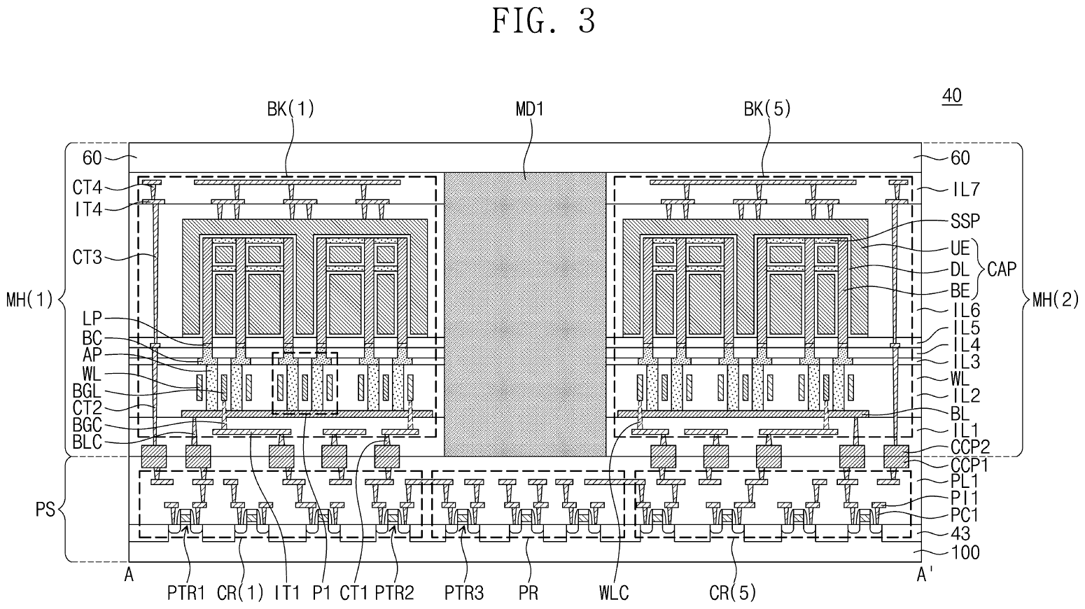

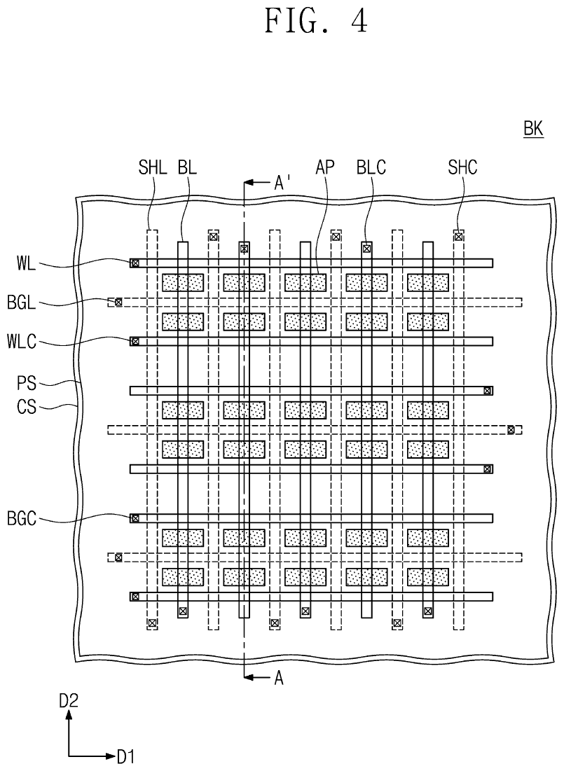

FIG. 4 is a plan view of a memory bank region according to embodiments of the inventive concept.

Referring to FIGS. 1A to 4, the memory bank regions BK may each include a plurality of cell array regions 10 (FIG. 1A) (or page region or mat region) arranged in a two-dimensional array form along the first direction D1 and the second direction D2. The bit lines BL and the shield lines SHL are arranged on the first cell interlayer insulating layer IL1 in the memory bank region BK. The bit lines BL and the shield lines SHL may extend in the second direction D2 and may be spaced apart from each other in the first direction D1. The shield lines SHL may be interposed between the bit lines BL, respectively.

Referring to FIGS. 3 and 4, a bit line contact plug BLC may penetrate the first cell interlayer insulating layer IL1 and connect end portions of the bit lines BL to the second connection pads CCP2. Although not illustrated in FIG. 3, a shield line contact plug SHC may penetrate the first cell interlayer insulating layer IL1 and connect end portions of the shield lines SHL to the second connection pads CCP2. A word line contact plug WLC may partially penetrate the first cell interlayer insulating layer IL1 and the second cell interlayer insulating layer IL2 and connect an end portion of the word line WL to the first cell line IT1. A back gate line contact plug BGC may partially penetrate the first cell interlayer insulating layer IL1 and the second cell interlayer insulating layer IL2 and connect an end portion of the back gate line BGL to the first cell line IT1.

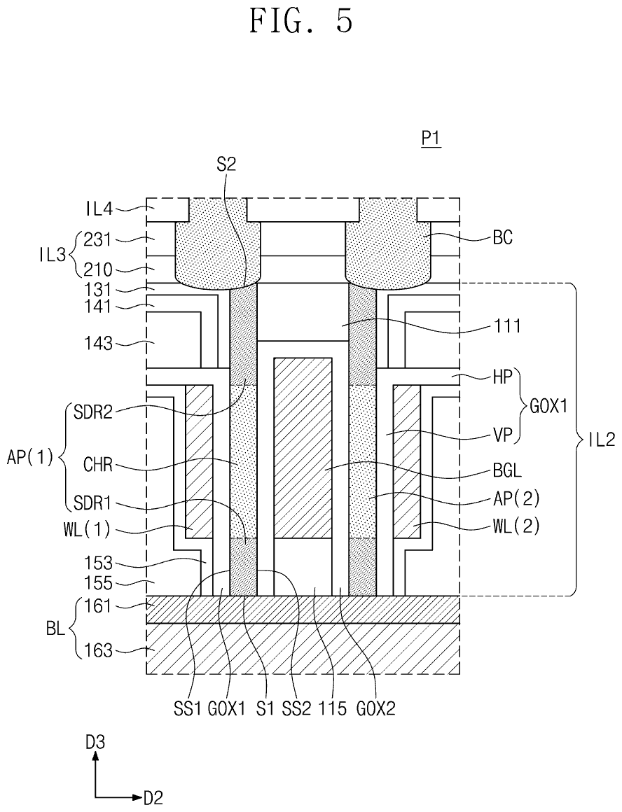

FIG. 5 is an enlarged view of portion PI of FIG. 3 according to embodiments of the inventive concept.

Referring to FIGS. 3 to 5, the bit lines BL may each include a polysilicon pattern 161 and a metal pattern 163 that are sequentially stacked. The shield lines SHL may each have at least one of the polysilicon pattern 161 or the metal pattern 163. A level of an upper surface of each of the bit lines BL may be equal to (i.e., coplanar with) or different from a level of an upper surface of each of the shield lines SHL. A level of a lower surface of each of the bit lines BL may be equal to (i.e., coplanar with) or different from a level of a lower surface of each of the shield lines SHL. The metal pattern 163 may include a conductive metal nitride (e.g., titanium nitride, tantalum nitride, etc.) and metal (e.g., tungsten, titanium, tantalum, etc.). The metal pattern 163 may also include a metal silicide such as titanium silicide, cobalt silicide, or nickel silicide.

Active patterns AP may include a pair of a first active pattern AP(1) and second active pattern AP(2) adjacent to each other. The active patterns AP may be formed of a single-crystalline semiconductor material. For example, the active patterns AP may be formed of single crystalline silicon. Each of the first active pattern AP(1) and the second active pattern AP(2) may have a length in the first direction D1, a width in the second direction D2, and a height in a direction perpendicular to the first and second directions D1 and D2. Each of the first active pattern AP(1) and the second active pattern AP(2) may have a substantially uniform width. A length of each of the first active pattern AP(1) and the second active pattern AP(2) may be larger than a line width of the bit line BL.

Each of the first active pattern AP(1) and the second active pattern AP(2) may have a first surface S1 and a second surface S2 opposite to each other in the third direction D3, which is perpendicular to the first direction D1 and the second direction D2. In an example, the first surfaces S1 of the first active pattern AP(1) and second active pattern AP(2) may be in contact with the polysilicon pattern 161 of the bit line BL, and, when the polysilicon pattern 161 is not provided, may be in contact with the metal pattern 163.

Each of the first active pattern AP(1) and the second active pattern AP(2) may have a first side surface SS1 and a second side surface SS2 opposite to each other in the second direction D2. The first side surface SS1 of the first active pattern AP(1) may be adjacent to a first word line WL(1), and the second side surface SS2 of the second active pattern AP(2) may be adjacent to a second word line WL(2).

Each of the first active pattern AP(1) and the second active pattern AP(2) may include a first dopant region SDR1 adjacent to the bit line BL, a second dopant region SDR2 adjacent to a storage node contact BC, and a channel region CHR between the first and second dopant regions SDR1 and SDR2. The first and second dopant regions SDR1 and SDR2 are dopant-doped regions in the first active pattern AP(1) and the second active pattern AP(2), and a dopant concentration in the first active pattern AP(1) and the second active pattern AP(2) may be higher than a dopant concentration in the channel region CHR.

A portion of the word line WL adjacent to one active pattern AP may function as a gate electrode and the first and second dopant regions SDR1 and SDR2 doped in the one active pattern AP may function as a source/drain region so as to function as the selection element TR or vertical channel transistor of FIG. 1B.

The channel regions CHR of the first active pattern AP(1) and second active pattern AP(2) may be controlled by the first and second word lines WL(1) and WL(2) and the back gate lines BGL when a semiconductor memory device operates. Since the first active pattern AP(1) and the second active pattern AP(2) are formed of a single-crystalline semiconductor material, leakage current characteristics may be improved when a semiconductor memory device operates.

The back gate lines BGL may be arranged spaced a certain distance apart from each other in the second direction D2 on the bit lines BL. The back gate lines BGL may extend in the first direction D1 across the bit lines BL.

The back gate lines BGL may each be arranged between a pair of the first active pattern AP(1) and the second active pattern AP(2) adjacent to each other in the second direction D2. Namely, the first active pattern AP(1) may be disposed on one side of each of the back gate lines BGL, and the second active pattern AP(2) may be disposed on the other side. The back gate lines BGL may have a lower height than the first active pattern AP(1) and the second active pattern AP(2) in a vertical direction.

The back gate line BGL may have a first surface close to the bit line BL and a second surface close to the storage node contact BC. The first and second surfaces of the back gate line BGL may be vertically spaced apart from the first and second surfaces S1 and S2 of the first active pattern AP(1) and second active pattern AP(2).

A level of an upper surface of each of the back gate lines BGL may be equal to or different from a level of an upper surface of each of the word lines WL. As used herein a “level” may refer to a vertical distance (e.g., in the direction D3) relative to a reference element or layer (e.g., the bit line BL). A level of a lower surface of each of the back gate lines BGL may be equal to or different from a level of a lower surface of each of the word lines WL.

The back gate lines BGL may include, for example, doped polysilicon, conductive metal nitride (e.g., titanium nitride, tantalum nitride, etc.) and metal (e.g., tungsten, titanium, tantalum, etc.), conductive metal silicide, conductive metal oxide, or a combination thereof.

When a semiconductor memory device operates, a negative voltage may be applied to the back gate lines BGL, and the back gate lines BGL may increase a threshold voltage of a vertical channel transistor. That is, deterioration of leakage current characteristics, due to a reduction in the threshold voltage caused by a small size of the vertical channel transistor, may be prevented.

The second cell interlayer insulating layer IL2 may include layers 111, 115, GOX1, GOX2, 131, 141, 143, 153, and 155 formed of an insulating material. A first insulating pattern 111 may be disposed between the first active pattern AP(1) and second active pattern AP(2) adjacent to each other in the second direction D2. The first insulating pattern 111 may be disposed between the second dopant regions SDR2 of the first active pattern AP(1) and second active pattern AP(2). The first insulating pattern 111 may include, for example, a silicon oxide layer, a silicon oxynitride layer, or a silicon nitride layer.

A first back gate insulating layer GOX2 may be disposed between each back gate line BGL and the first and second active patterns AP(1) and AP(1) and between the back gate line BGL and the first insulating pattern 111. The first back gate insulating layer GOX2 may include vertical portions covering two side surfaces of the back gate line BGL and a horizontal portion connecting the vertical portions. The horizontal portion of the first back gate insulating layer GOX2 may be closer to the storage node contact BC than the bit line BL, and may cover the second surface of the back gate line BGL. The first back gate insulating layer GOX2 may be formed of, for example, a silicon oxide layer, a silicon oxynitride layer, a high dielectric layer with a higher dielectric constant than silicon oxide layer, or a combination thereof.

A back gate capping pattern 115 may be disposed between the bit lines BL and the back gate line BGL. The back gate capping pattern 115 may be formed of an insulating material, and a lower surface of the back gate capping pattern 115 may be in contact with the polysilicon pattern 161 of the bit lines BL. The back gate capping pattern 115 may be disposed between the vertical portions of the first back gate insulating layer GOX2. A thickness of the back gate capping pattern 115 between the bit lines BL may be different from a thickness of the back gate capping pattern 115 on the bit lines BL.

The first word line WL(1) and the second word line WL(2) may include, for example, doped polysilicon, metal, conductive metal nitride, conductive metal silicide, conductive metal oxide, or a combination thereof. Cell gate insulating layers GOX1 may be arranged between the first and second word lines WL(1) and WL(2) and the first and second active patterns AP(1) and AP(2). The cell gate insulating layers GOX1 may extend in the first direction D1 in parallel with the first and second word lines WL(1) and WL(2).

The cell gate insulating layer GOX1 may be formed of a silicon oxide layer, a silicon oxynitride layer, a high (k) dielectric layer with a higher dielectric constant than silicon oxide layer, or a combination thereof. The high dielectric layer may be formed of metal oxide or metal oxynitride. For example, a high dielectric layer that may be used as a gate insulating layer may be formed of HfO₂, HfSiO, HfSiON, HfTaO, HfTiO, HfZrO, ZrO₂, Al₂O₃, or a combination thereof, but is not limited thereto.

The cell gate insulating layer GOX1 may cover the first side surface SS1 of the first active pattern AP(1) and the second side surface SS2 of the second active pattern AP(2). The cell gate insulating layer GOX1 may have a substantially uniform thickness. The cell gate insulating layers GOX1 may each include a vertical portion VP adjacent to the first and second active patterns AP(1) and AP(2) and a horizontal portion HP protruding from the vertical portion VP in the second direction D2. For example, a pair of the first and second word lines WL(1) and WL(2) may be arranged on the horizontal portion HP of each of the cell gate insulating layers GOX1. The cell gate insulating layers GOX1 may be arranged spaced apart from each other and may be mirror symmetrical to each other.

A second insulating pattern 143 may be disposed between the horizontal portion HP of the cell gate insulating layer GOX1 and the storage node contacts BC. For example, the second insulating pattern 143 may include silicon oxide. First and second etch stop layers 131 and 141 may be arranged between the second insulating pattern 143 and the second dopant regions SDR2 of the first and second active patterns AP(1) and AP(2).

On the cell gate insulating layer GOX1, the first and second word lines WL(1) and WL(2) may be separated from each other by a third insulating pattern 155. The third insulating pattern 155 may extend in the first direction D1 between the first and second word lines WL(1) and WL(2). A first capping layer 153 may be disposed between the third insulating pattern 155 and the first and second word lines WL(1) and WL(2). The first capping layer 153 may have a substantially uniform thickness.

The third cell interlayer insulating layer IL3 may include an etch stop layer 210 and an interlayer insulating layer 231 sequentially stacked. The storage node contacts BC may penetrate the interlayer insulating layer 231 and the etch stop layer 210 and may be connected to the first and second active patterns AP(1) and AP(2), respectively. Namely, the storage node contacts BC may be connected to the second dopant regions SDR2 of the first and second active patterns AP(1) and AP(2), respectively. The storage node contacts BC may have a lower width that is larger than an upper width thereof. The storage node contacts BC adjacent to each other may be separated from each other by the fourth cell interlayer insulating layer IL4. The storage node contacts BC may each have various shapes such as a circular shape, elliptical shape, rectangular shape, square shape, rhombic shape, and hexagonal shape in a plan view. The storage node contacts BC may be arranged in a matrix form along the first direction D1 and the second direction D2. The storage node contacts BC may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto.

Locations of the capacitor CAP, the active pattern AP, the bit lines BL, and the like in the memory die MH may vary without being limited to the locations illustrated in FIG. 3. For example, the bit line BL, the active pattern AP, and the capacitor CAP may be sequentially located from the second substrate 60.

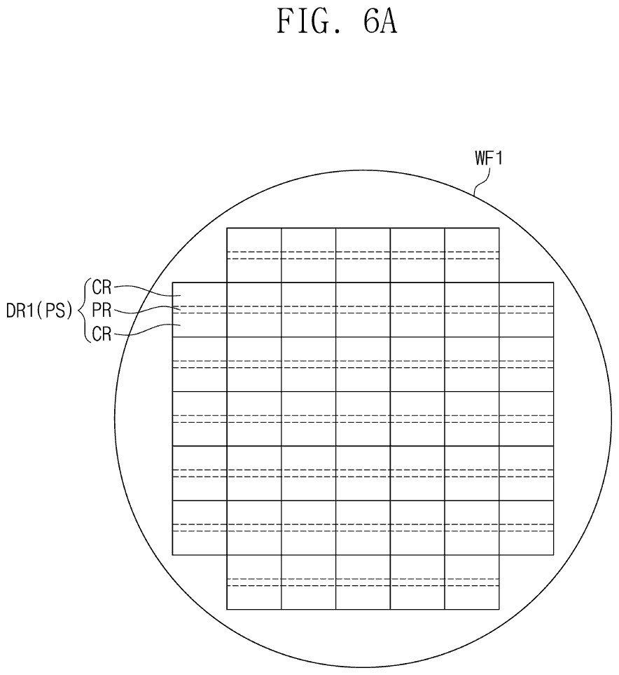

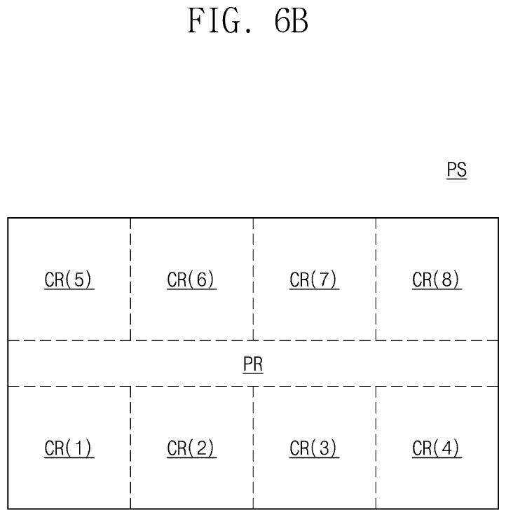

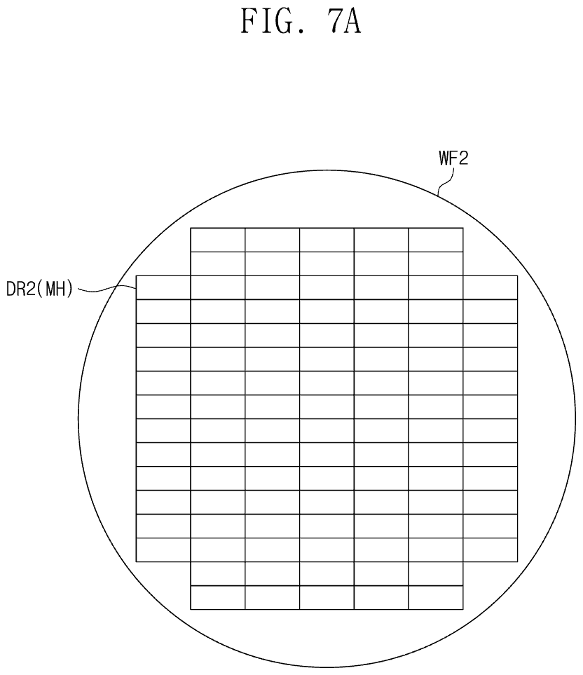

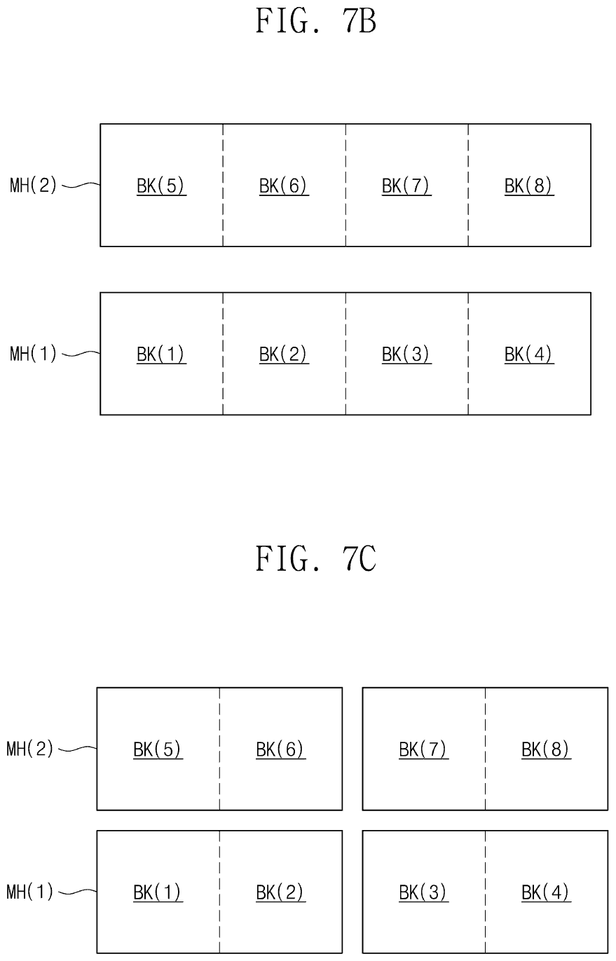

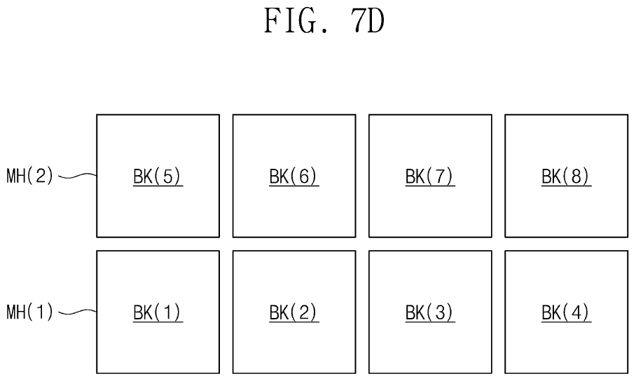

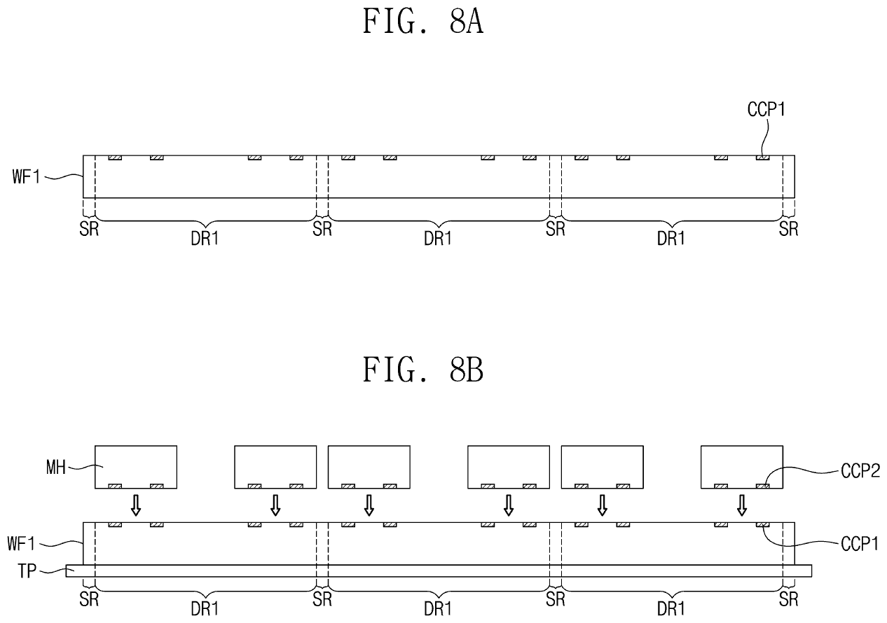

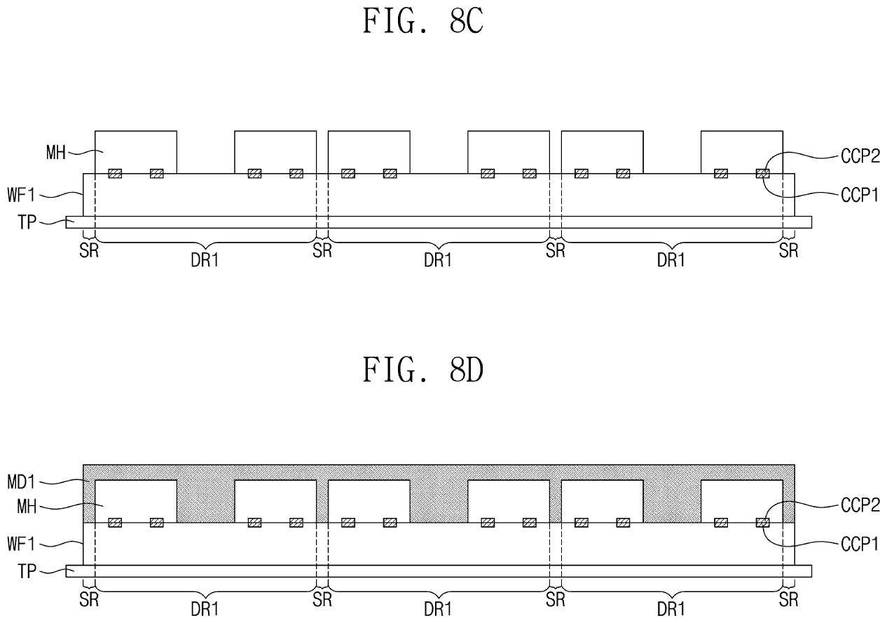

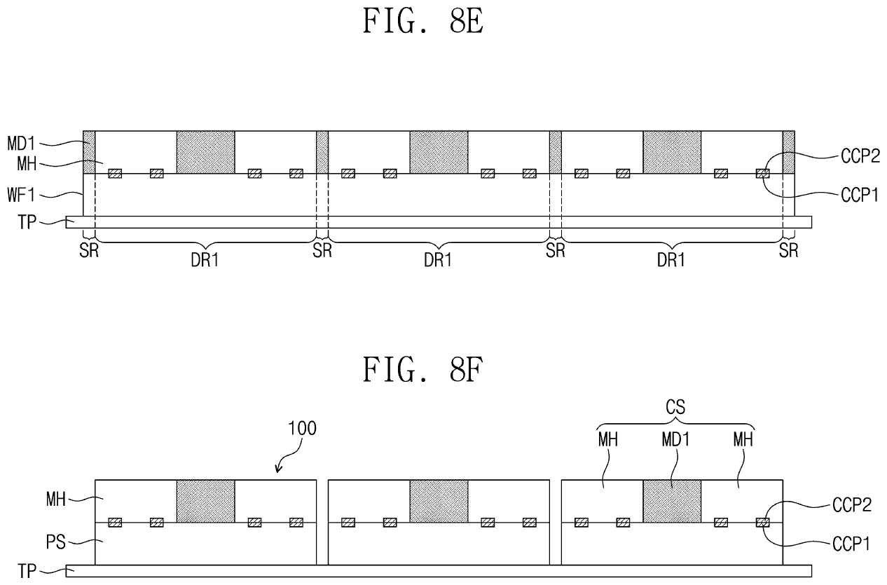

FIG. 6A is a plan view of a first wafer for producing a logic die of an embodiment of the inventive concept. FIG. 6B is a plan view of a logic die of an embodiment of the inventive concept. FIG. 7A is a plan view of a second wafer for producing a memory die of an embodiment of the inventive concept. FIGS. 7B to 7D are plan views of memory dies of an embodiment of the inventive concept. FIGS. 8A to 8F are cross-sectional views illustrating a process of manufacturing the semiconductor chip of FIG. 2A.

Referring to FIGS. 6A, 6B, and 8A, a first wafer WF1 is prepared. The first wafer WF1 includes first device regions DR1 and a separation region SR therebetween. The separation region SR may be a scribe lane region. The first device regions DR1 may have the same structure as the logic dies PS. That is, the first device regions DR1 may become the logic die PS after sawing the first wafer WF1. The first wafer WF1 may be provided only to produce the logic dies PS. That is, the first wafer WF1 may only include logic dies PS. The first device region DR1 or the logic die PS may include the core regions CR and the peripheral circuit region PR. The first connection pads CCP1 may be arranged in the first device regions DR1 of the first wafer WF1.

Referring to FIGS. 7A to 7D and 8B, the first wafer WF1 is bonded onto a carrier substrate TP. The carrier substrate TP may be a tape, for example. A second wafer WF2 is prepared. The second wafer WF2 includes second device regions DR2 and a separation region SR therebetween. The second device regions DR2 may have the same structure as the memory dies MH. That is, the second device regions DR2 may become the memory dies MH after sawing the second wafer WF2. The second wafer WF2 may be provided only to produce the memory dies MH. That is, the second wafer WF2 may only include memory dies MH. Referring to FIG. 7B, each memory die MH includes four memory bank regions BK arranged side by side. A dummy space is not provided between the memory bank regions BK in one memory die MH. In another example, referring to FIG. 7C, each memory die MH includes two memory bank regions BK. In another example, referring to FIG. 7D, each memory die MH includes one memory bank region BK. A plurality of memory dies MH are formed by sawing the second wafer WF2. The memory dies MH may each include the second connection pads CCP2.

Referring to FIGS. 8B and 8C, the memory dies MH are located on the first device region DR1 of the first wafer WF1. The memory dies MH are bonded onto the first device region DR1 of the first wafer WF1 by performing a thermal compression process after bring the second connection pads CCP2 into contact with the first connection pads CCP1, respectively.

Referring to FIG. 8D, the first mold layer MD1 covering the memory dies MH and the first wafer WF1 is formed by performing a molding process.

Referring to FIG. 8E, a grinding process is performed on the first mold layer MD1 to remove a portion of the first mold layer MD1 and expose upper surfaces of the memory dies MH. The term “exposed,” may be used to describe relationships between elements and/or certain intermediate processes in fabricating a completed semiconductor device, but may not necessarily require exposure of the particular region, layer, structure or other element in the context of the completed device.

Referring to FIG. 8F, a sawing process is performed on the first wafer WF1 and the first mold layer MD1 to remove the separation regions SR of the first wafer WF1 and the first mold layer MD1 thereon. Accordingly, semiconductor chips 100 including the logic die PS and the cell structure CS may be formed. The memory dies MH and the first mold layer MD1 may constitute the cell structure CS. In a subsequent process, the semiconductor chips 100 may be separated from the carrier substrate TP.

According to a comparative example of the inventive concept, the cell structure may be configured with one memory die without the first mold layer MD1 of FIG. 2A. The second device regions of the second wafer of the comparative example may have the same size as the logic die PS of FIG. 6B or the cell structure CS of FIG. 2A. Each of the second device regions of the comparative example is formed to have the memory bank regions BK(1) to BK(8) (to be respectively overlapped by the core regions CR of the logic die PS) and a dummy region (to be overlapped by the peripheral circuit region PR of the logic die PS). As described above, since each of the second device regions is formed to have a dummy region in the comparative example, the number of cell structures (or the number of memory dies) that may be produced using the second wafer may be reduced.

However, in an embodiment of the inventive concept, only the memory bank regions BK are arranged in the second device region DR2 (or memory die MH) of the second wafer WF2, and there is no dummy space (to be overlapped by the peripheral circuit region PR of the logic die PS) therein, and thus the number of cell structures (or the number of memory dies) that may be produced using the second wafer WF2 may increase. Therefore, the production cost may be reduced, and the yield may be improved.

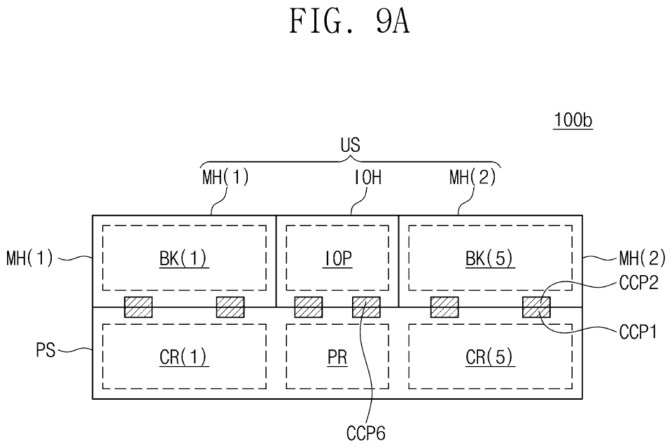

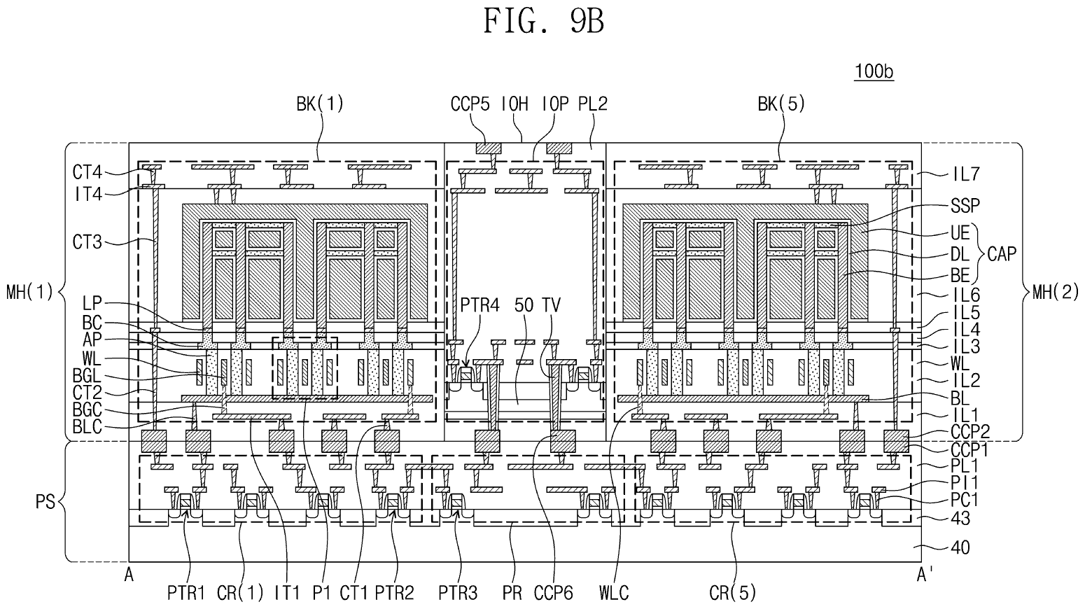

FIG. 9A is a cross-sectional view of a semiconductor chip according to embodiments of the inventive concept.

Referring to FIG. 9A, a semiconductor chip 100b according to the present example includes the logic die PS and an upper structure US disposed thereon. The upper structure US may include the first and second memory dies MH(1) and MH(2) and an input/output die IOH therebetween. The input/output die IOH may overlap the peripheral circuit region PR of the logic die PS in the vertical direction. The input/output die IOH may include an I/O region IOP in which input/output circuits for exchanging data with the outside of the semiconductor chip 100b (i.e., with external devices) are arranged. The input/output die IOH may include sixth connection pads CCP6 arranged at a lower end or surface thereof. The sixth connection pads CCP6 may be in contact with some of the first connection pads CCP1 at an upper end or surface of the logic die PS, respectively. The first and second memory dies MH(1) and MH(2) may be in contact with the input/output die IOH. The semiconductor chip 100b may exclude (i.e., may be free of) the first mold layer MD1 of FIG. 2A. Alternatively, in another example, a mold layer may be interposed between the first and second memory dies MH(1) and MH(2) and the input/output die IOH.

FIG. 9B is a cross-sectional view of a semiconductor chip according to embodiments of the inventive concept.

Referring to FIG. 9B, the memory die MH may exclude (i.e., may be free of) the second substrate 60 of FIG. 3. The input/output die IOH may include a third substrate 50, fourth peripheral transistors PTR4, through-vias TV, a second peripheral interlayer insulating layer PL2, fifth connection pads CCP5, and the sixth connection pads CCP6. The fourth peripheral transistors PTR4 may be disposed on the third substrate 50 and may have a form of a planar transistor. The fifth connection pads CCP5 may be arranged at an upper end or surface of the input/output die IOH. The sixth connection pads CCP6 may be arranged at a lower end or surface of the input/output die IOH. One of the through-vias TV may penetrate the third substrate 50 and connect a terminal of one of the fourth peripheral transistors PTR4 to one of the sixth connection pads CCP6. The fourth peripheral transistors PTR4 may constitute some of the input/output circuits.

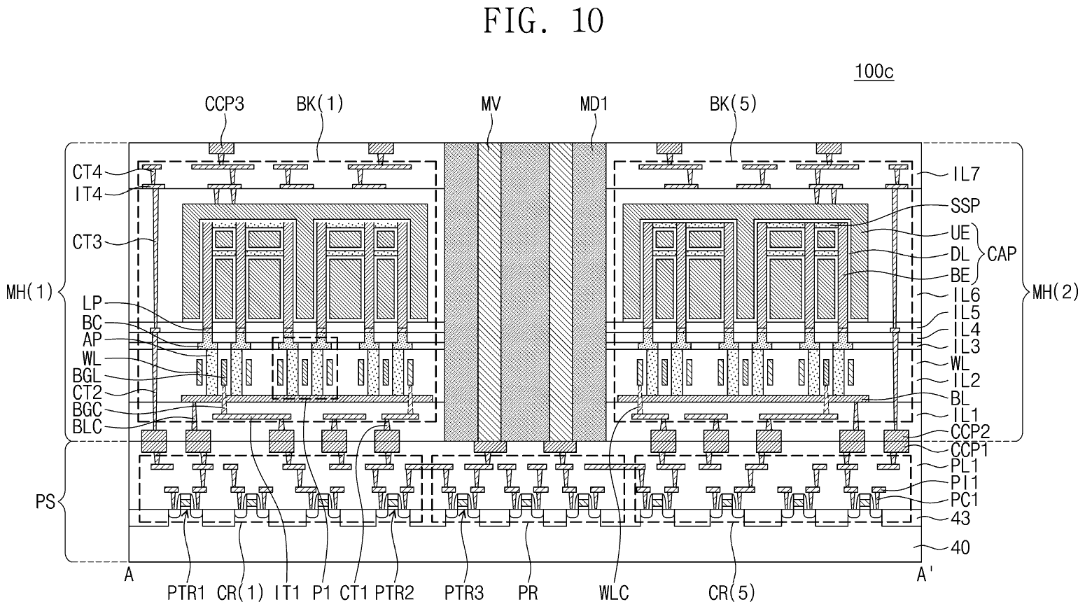

FIG. 10 is a cross-sectional view of a semiconductor chip according to embodiments of the inventive concept.

Referring to FIG. 10, a semiconductor chip 100c according to the present example may further include mold vias MV penetrating the first mold layer MD1 in the structure illustrated in FIG. 3, and third connection pads CCP3 at the upper ends or surfaces of the memory dies MH. Some of the first connection pads CCP1 of the logic die PS may be arranged at an upper end or surface of the peripheral circuit region PR. The mold vias MV may be in contact with some of the first connection pads CCP1, respectively. The memory die MH may exclude (i.e., may be free of) the second substrate 60 of FIG. 3. Other structures may be the same as/similar to those illustrated in FIG. 3.

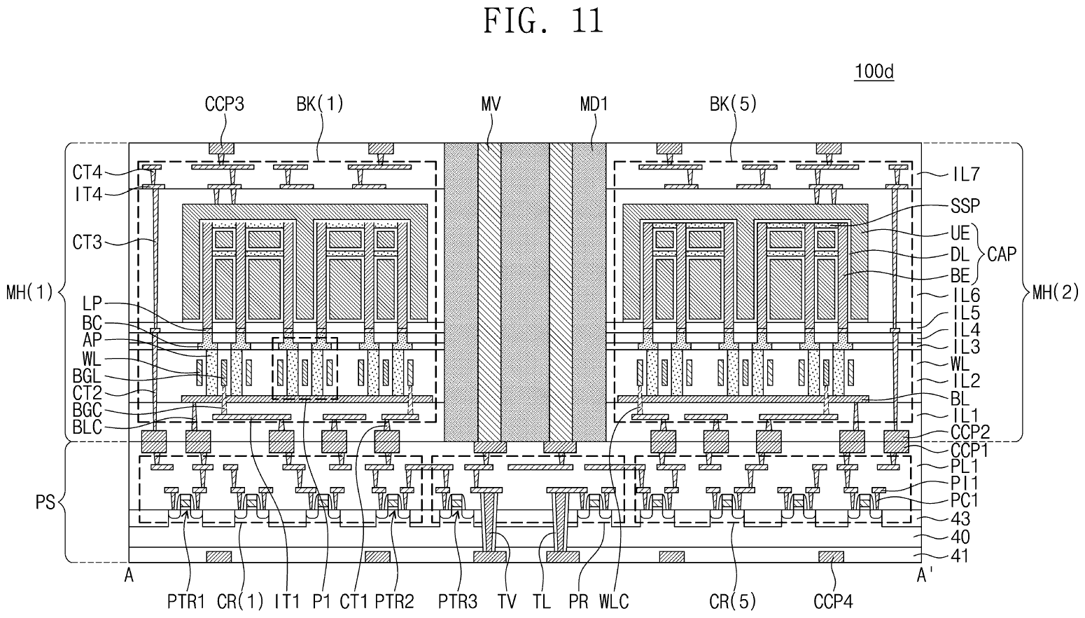

FIG. 11 is a cross-sectional view of a semiconductor chip according to embodiments of the inventive concept.

Referring to FIG. 11, a semiconductor chip 100d according to the present example may further include a through-via TV, a via insulating layer TL, a back side insulating layer 41, and fourth connection pads CCP4 in the structure illustrated in FIG. 10. A lower surface of the first substrate 40 may be covered with the back side insulating layer 41. The through-via TV may penetrate the first substrate 40 and may be connected to the fourth connection pads CCP4. The via insulating layer TL may be interposed between the through-via TV and the first substrate 40. The fourth connection pads CCP4 may be arranged in the back side insulating layer 41. Other structures may be the same as/similar to those illustrated in FIG. 10.

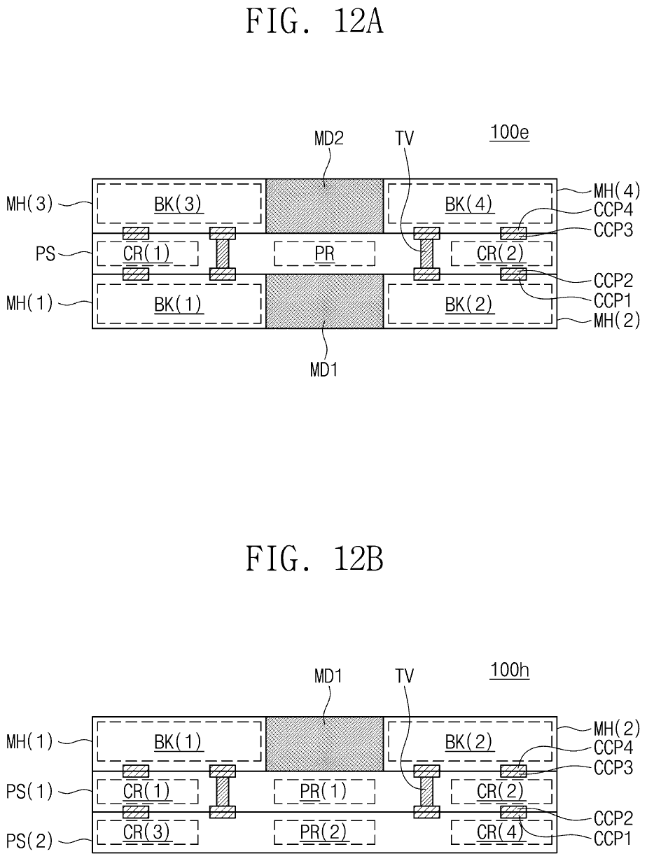

FIG. 12A is a cross-sectional view of a semiconductor chip according to embodiments of the inventive concept.

Referring to FIG. 12A, a semiconductor chip 100e according to the present example includes the logic die PS, the first to fourth memory dies MH(1) to MH(4), and first and second mold layers MD1 and MD2. The logic die PS may include through-vias TV penetrating the inside of the logic die PS. The first memory die MH(1), the first mold layer MD1, and the second memory die MH(2) are arranged under or beneath the logic die PS. The third memory die MH(3), the second mold layer MD2, and the fourth memory die MH(4) are arranged on or above the logic die PS.

The first and second memory dies MH(1) and MH(2) may include the first connection pads CCP1 arranged at upper ends or surfaces thereof. The logic die PS includes the second connection pads CCP2 arranged at a lower end or surface thereof and the third connection pads CCP3 arranged at an upper end or surface thereof. The third and fourth memory dies MH(3) and MH(4) may include the fourth connection pads CCP4 arranged at lower ends or surfaces thereof. The first connection pads CCP1 may be in contact with the second connection pads CCP2, respectively. The third connection pads CCP3 may be in contact with the fourth connection pads CCP4, respectively.

The first to fourth memory dies MH(1) to MH(4) may each include at least one memory bank region BK. The memory bank regions BK may respectively overlap the core regions CR of the logic die PS in the vertical direction. The first memory bank region BK(1) of the first memory die MH(1) and the third memory bank region BK(3) of the third memory die MH(3) may be connected to the first core region CR(1) of the logic die PS. The second memory bank region BK(2) of the second memory die MH(2) and the fourth memory bank region BK(4) of the fourth memory die MH(4) may be connected to the second core region CR(2) of the logic die PS. The first and second mold layers MD1 and MD2 may overlap the peripheral circuit region PR of the logic die PS in the vertical direction. Other structures may be the same as/similar to those described with reference to FIGS. 1A to 11.

FIG. 12B is a cross-sectional view of a semiconductor chip according to embodiments of the inventive concept.

Referring to FIG. 12B, a semiconductor chip 100h according to the present example includes first and second logic dies PS(1) and PS(2), the first and second memory dies MH(1) and MH(2), and the first and second mold layers MD1 and MD2. The first logic die PS(1) may include through-vias TV penetrating the inside of the first logic die PS(1). The first memory die MH(1(1)), the first mold layer MD1, and the second memory die MH(2) are arranged on the first logic die PS(1). The second logic die PS(2) is disposed under the first logic die PS(1). The first logic die PS(1) may include the first and second core regions CR(1) and CR(2) and a first peripheral circuit region PR(1) therebetween. The second logic die PS(2) may include the third and fourth core regions CR(3) and CR(4) and a second peripheral circuit region PR(2) therebetween. Other structures may be the same as/similar to those described with reference to FIGS. 1A to 12.

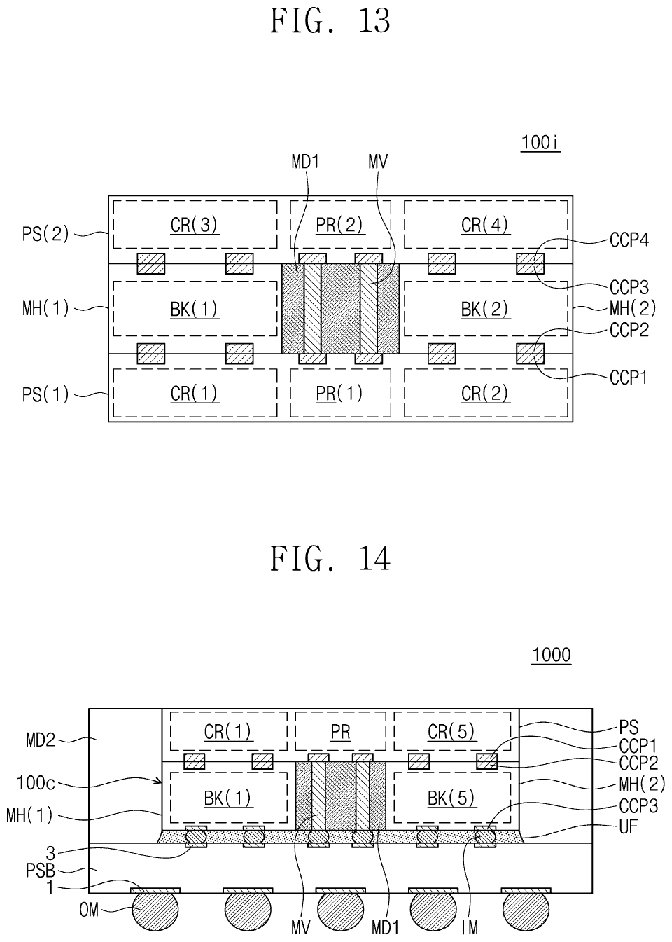

FIG. 13 is a cross-sectional view of a semiconductor chip according to embodiments of the inventive concept.

Referring to FIG. 13, a semiconductor chip 100i according to the present example includes the first logic die PS(1), the second logic die PS(2), the first and second memory dies MH(1) and MH(2), and the first mold layer MD1 and mold vias MV. The first and second memory dies MH(1) and MH(2) and the first mold layer MD1 are arranged on the first logic die PS(1). The second logic die PS(2) is disposed on the first and second memory dies MH(1) and MH(2) and the first mold layer MD1. The mold vias MV may penetrate the first mold layer MD1 and connect the first logic die PS(1) to the second logic die PS(2). The first memory bank region BK(1) of the first memory die MH(1) may be connected to the first core region CR(1) of the first logic die PS(1) and the third core region CR(3) of the second logic die PS(2). The second memory bank region BK(2) of the second memory die MH(2) may be connected to the second core region CR(2) of the first logic die PS(1) and the fourth core region CR(4) of the second logic die PS(2). Other structures may be the same as/similar to those described with reference to FIGS. 1A to 12B.

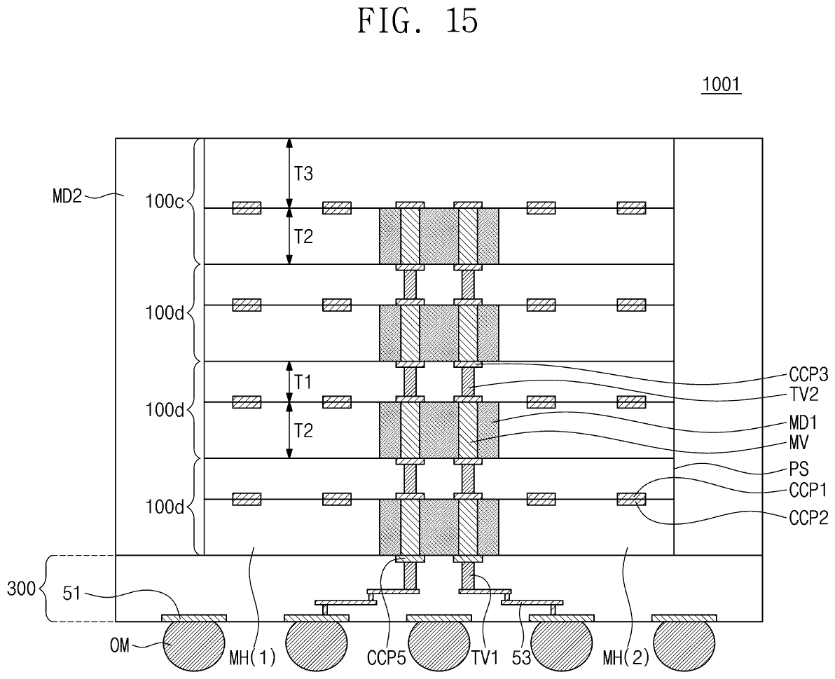

FIG. 14 is a cross-sectional view of a semiconductor package according to embodiments of semiconductor package.

Referring to FIG. 14, a semiconductor package 1000 according to the present example includes a package substrate PSB, the semiconductor chip 100c mounted on the package substrate PSB, and the second mold layer MD2 covering the semiconductor chip 100c. The semiconductor chip 100c may also be referred to as a “chip structure”. The package substrate PSB may be a double-sided or multi-layer printed circuit board. Alternatively, the package substrate PSB may be an interposer substrate or a redistribution substrate. The package substrate PSB includes first upper substrate pads 3 arranged at an upper end or surface thereof and first lower substrate pads 1 arranged at a lower end or surface thereof. External connection members OM may be bonded to the first lower substrate pads 1. The semiconductor chip 100c may have a structure in which the semiconductor chip described with reference to FIG. 10 is turned upside down. The semiconductor chip 100c may be bonded to the package substrate PSB through internal connection members IM. The internal connection members IM and the external connection members OM may each include at least one of a conductive bump, a conductive pillar, or a solder ball. An underfill layer UF may be interposed between the semiconductor chip 100c and the package substrate PSB. The underfill layer UF may further include an organic filler or inorganic filler. The organic filler may include, for example, a polymer material. The inorganic filler may include, for example, silicon oxide (SiO₂).

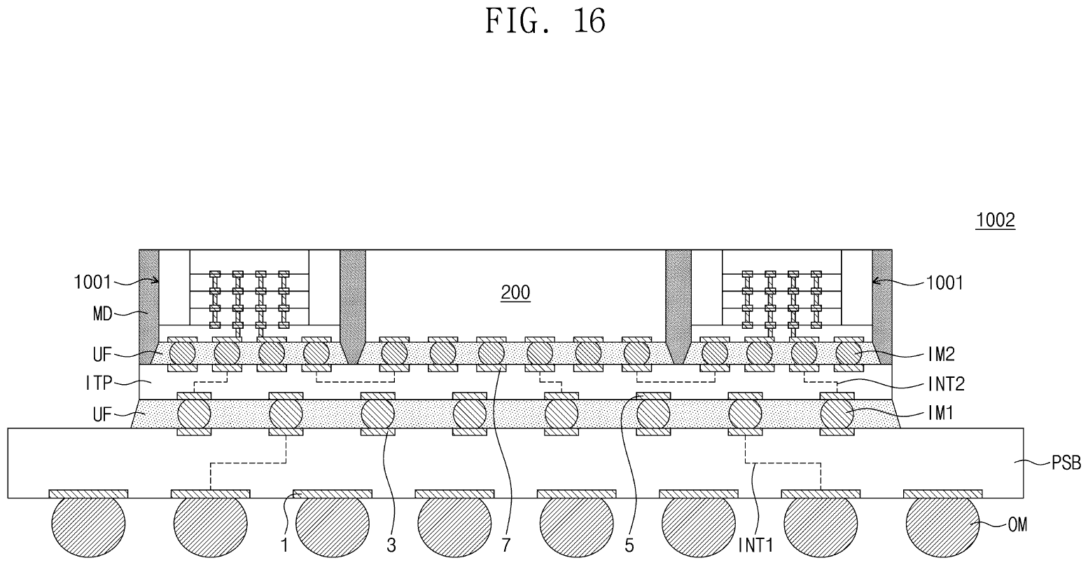

FIG. 15 is a cross-sectional view of a semiconductor package according to embodiments of semiconductor package.

Referring to FIG. 15, a semiconductor package 1001 according to the present example may be a high bandwidth memory (HBM) chip. The semiconductor package 1001 includes a buffer die 300, first and second semiconductor chips 100d and 100c stacked on the buffer die 300, and the second mold layer MD2 covering the first and second semiconductor chips 100d and 100c. The first semiconductor chip 100c may also be referred to as a “first chip structure”. The second semiconductor chip 100d may also be referred to as a “second chip structure”. The buffer die 300 may include therein first through-vias TV1 and buffer lines 53. Fifth connection pads CCP5 may be arranged at an upper end or surface of the buffer die 300 and buffer conductive pads 51 may be arranged at a lower end or surface of the buffer die 300. The external connection members OM may be bonded to the buffer conductive pads 51.

The first semiconductor chips 100d may have a structure in which the semiconductor chip described with reference to FIG. 11 is turned upside down. The second semiconductor chip 100c is bonded onto an uppermost one among the first semiconductor chips 100d. The second semiconductor chip 100c may have a structure in which the semiconductor chip described with reference to FIG. 10 is turned upside down.

The first and second semiconductor chips 100d and 100c may each include the logic die PS, the first and second memory dies MH(1) and MH(2) bonded thereunder, the first mold layer MD1, and the mold vias MV.

In the first semiconductor chip 100d, the logic die PS may have a first thickness T1, and the memory dies MH may have a second thickness T2. The first thickness T1 may be different from (e.g., greater than or less than) the second thickness T2. The logic die PS may include the third connection pads CCP3 arranged at an upper end or surface thereof and the first connection pads CCP1 arranged at a lower end or surface thereof. The memory dies MH may include the second connection pads CCP2 arranged at an upper end or surface thereof.

In the second semiconductor chip 100c, the logic die PS may have a third thickness T3, and the memory dies MH may have the second thickness T2. The third thickness T3 may be different from the second thickness T2. The third thickness T3 may be greater than the first thickness T1.

In the first semiconductor chip 100d, the logic die PS may include a second through-via TV2. In the second semiconductor chip 100c, the logic die PS may exclude (i.e., may be free of) the second through-via TV2. Other structures may be the same as/similar to those described above.

FIG. 16 is a cross-sectional view of a semiconductor package according to embodiments of semiconductor package.

Referring to FIG. 16, a semiconductor package 1002 according to the present example may include the package substrate PSB, an interposer substrate ITP, a first semiconductor chip 200, sub-semiconductor packages 1001, and a mold layer MD. The package substrate PSB may be a double-sided or multi-layer printed circuit board. The package substrate PSB may include first upper substrate pads 3, first lower substrate pads 1, and first internal lines INT1. The first upper substrate pads 3, the first lower substrate pads 1, and the first internal lines INT1 may each include metal such as copper, aluminum, and gold. The first internal lines INT1 may connect at least some of the first upper substrate pads 3 to the first lower substrate pads 1. The external connection members OM may be bonded to the first lower substrate pads 1.

The interposer substrate ITP is located on the package substrate PSB. The interposer substrate ITP may include silicon. The interposer substrate ITP may be a semiconductor die. The interposer substrate ITP may include second upper substrate pads 7, second lower substrate pads 5, and second internal lines INT2. The second upper substrate pads 7, the second lower substrate pads 5, and the second internal lines INT2 may each include metal such as copper, aluminum, and tungsten. Some of the second internal lines INT2 may connect some of the second upper substrate pads 7 to the second lower substrate pads 5. Some others of the second internal lines INT2 may connect the sub-semiconductor packages 1001 to the first semiconductor chip 200.

The interposer substrate ITP may be electrically connected by first internal connection members IM1 to the package substrate PSB. The first internal connection members IM1 may be a solder ball. The underfill layer UF may be interposed between the interposer substrate ITP and the package substrate PSB.

The first semiconductor chip 200 and the sub-semiconductor packages 1001 may be arranged on the interposer substrate ITP. The first semiconductor chip 200 may be disposed between the sub-semiconductor packages 1001. The first semiconductor chip 200 may be a large scale integration (LSI) chip, a logic circuit chip, a processor chip, or an application-specific integrated circuit (ASIC) chip. The sub-semiconductor packages 1001 may each be a memory chip such as an HBM chip, a hybrid memory cubic (HMC) chip, or the like. The sub-semiconductor packages 1001 may have a structure that is the same as/similar to that of the semiconductor package 1001 described with reference to FIG. 15. The first semiconductor chip 200 may store data in the sub-semiconductor packages 1001 or perform processing/operation on data stored in the sub-semiconductor packages 1001.

The first semiconductor chip 200 and the sub-semiconductor packages 1001 may be electrically connected by second internal connection members IM2 to the interposer substrate ITP. The second internal connection members IM2 may be a solder ball. The underfill layer UF may be interposed between the interposer substrate ITP and the first semiconductor chip 200 and between the interposer substrate ITP and the sub-semiconductor packages 1001. The underfill layer UF may be formed of a non-conductive layer (NCF). The underfill layer UF may include a thermosetting resin or photocurable resin. A space between the first semiconductor chip 200 and the sub-semiconductor packages 1001 may be filled with the mold layer MD.

In a semiconductor chip and a semiconductor package according to an embodiment of the inventive concept, memory dies having only a (i.e., a dedicated) memory function are arranged on a logic die having only a (i.e., a dedicated) logic function, and thus the memory capacity may be increased while reducing the horizontal size of the semiconductor chip and the semiconductor package.

According to a method for manufacturing a semiconductor chip according to an embodiment of the inventive concept, a wafer for producing a memory die is manufactured so that only memory bank regions are arranged on the wafer and there is no dummy space to be overlapped by a peripheral circuit region of a logic die, and thus the number of cell structures that may be manufactured using the wafer may be increased. Therefore, production cost may be reduced, and yield may be improved.

Although embodiments of the present invention have been described with reference to the accompanying drawings, those of ordinary skill in the art could easily understood that the present invention can be carried out in other specific forms without changing the technical concept or essential features. Therefore, the above embodiments should be considered illustrative and should not be construed as limiting. The embodiments of FIGS. 2A to 16 may be combined with each other in any way.

What is claimed is:

1. A semiconductor chip comprising:
a first logic die;
first memory dies arranged side by side in a first direction on the first logic die; and
a first mold layer between the first memory dies,
wherein the first memory dies and the first mold layer are in contact with an upper surface of the first logic die,
wherein each of the first memory dies comprises first memory bank regions arranged side by side in a second direction intersecting the first direction, and
wherein the first logic die comprises first core regions overlapping the first memory bank regions, respectively, in a third direction that is perpendicular to the first and second directions.

2. The semiconductor chip of claim 1,
wherein the first logic die further comprises a peripheral circuit region overlapping the first mold layer, and
wherein the peripheral circuit region comprises column decoder circuits, row decoder circuits, an input/output circuit, a voltage generation circuit, and a fuse circuit.

3. The semiconductor chip of claim 1, further comprising:
an input/output die between the first memory dies, the input/output die comprising input/output circuits.

4. The semiconductor chip of claim 1,
wherein the first logic die further comprises first connection pads at the upper surface of the first logic die,
wherein each of the first memory dies further comprises second connection pads at a lower surface thereof, the second connection pads overlapping the first connection pads in the third direction, and
wherein the semiconductor chip further comprises mold vias penetrating the first mold layer and contacting a subset of the first connection pads.

5. The semiconductor chip of claim 1, wherein the first logic die further comprises:
a first substrate;
a peripheral interlayer insulating layer on a front side of the first substrate;
a back side insulating layer on a back side of the first substrate that is opposite the front side;
fourth connection pads in the back side insulating layer; and
through-vias extending into the first substrate and the back side insulating layer and electrically connected to the fourth connection pads, respectively.

6. The semiconductor chip of claim 1, wherein each of the first memory dies further comprises third connection pads at an upper surface thereof.

7. The semiconductor chip of claim 6, wherein each of the first memory dies further comprises:
active patterns extending in the third direction;
word lines extending alongside the active patterns;
bit lines under the active patterns; and
data storage elements on the active patterns opposite the bit lines.

8. The semiconductor chip of claim 1, comprising:
second memory dies arranged side by side in the first direction on the first logic die opposite the first memory dies; and
a second mold layer between the second memory dies,
wherein the second memory dies and the second mold layer are in contact with a lower surface of the first logic die that is opposite the upper surface,
each of the second memory dies comprises second memory bank regions arranged side by side in the second direction, and
the second memory bank regions overlap the first core regions, respectively, in the third direction.

9. The semiconductor chip of claim 1, further comprising:
a second logic die on the first memory dies and the first mold layer opposite the first logic die,
wherein the second logic die comprises second core regions overlapping the first memory bank regions, respectively, in the third direction.

10. The semiconductor chip of claim 1, further comprising:
a second logic die on a lower surface of the first logic die that is opposite the upper surface.

11. A semiconductor chip comprising:
a logic die;
memory dies arranged side by side in a first direction on the logic die; and
a mold layer between the memory dies,
wherein the logic die comprises:
a first substrate;
peripheral transistors on the first substrate;
a peripheral interlayer insulating layer on the peripheral transistors; and
peripheral lines in the peripheral interlayer insulating layer, and
wherein each of the memory dies comprises:
an active pattern extending perpendicular to an upper surface of the first substrate;
a word line adjacent to a side surface of the active pattern in the first direction;
a bit line under the active pattern;
a capacitor on the active pattern opposite the bit line; and
a cell interlayer insulating layer on the active pattern, the word line, the bit line, and the capacitor,
wherein the mold layer comprises a material different from respective materials of the cell interlayer insulating layer and the peripheral interlayer insulating layer.

12. The semiconductor chip of claim 11,
wherein each of the memory dies comprises memory bank regions arranged side by side in a second direction intersecting the first direction, and
wherein the logic die comprises core regions overlapping the memory bank regions, respectively.

13. The semiconductor chip of claim 12,
wherein the logic die further comprises a peripheral circuit region overlapping the mold layer in a third direction that is perpendicular to the first and second directions, and
wherein the peripheral circuit region comprises column decoder circuits, row decoder circuits, an input/output circuit, a voltage generation circuit, and a fuse circuit.

14. The semiconductor chip of claim 11,
wherein the logic die further comprises first connection pads at an upper surface of the logic die,
wherein each of the memory dies further comprises second connection pads arranged at a lower surface that is opposite the upper surface thereof, the second connection pads overlapping the first connection pads in a direction that is perpendicular to the upper surface of the first substrate, and
wherein the semiconductor chip further comprises mold vias extending into the mold layer and contacting a subset of the first connection pads.

15. The semiconductor chip of claim 11, wherein the logic die further comprises:
a back side insulating layer on a back side of the first substrate that is opposite the peripheral interlayer insulating layer;
fourth connection pads in the back side insulating layer; and
through-vias extending into the first substrate and the back side insulating layer and electrically connected to the fourth connection pads.

16. The semiconductor chip of claim 11,
wherein the logic die has a first thickness, and
wherein each of the memory dies has a second thickness different from the first thickness in a direction that is perpendicular to the upper surface of the first substrate.

17. A semiconductor package comprising:
a buffer die;
chip structures stacked on the buffer die; and
a first mold layer on the buffer die and the chip structures,
wherein each of the chip structures comprises:
a logic die;
memory dies bonded onto the logic die and arranged side by side in a first direction between the logic die and the buffer die;
a second mold layer between the memory dies; and
mold vias extending into the second mold layer,
wherein the logic die comprises first connection pads at an upper surface of the logic die, second connection pads at a lower surface of the logic die that is opposite the upper surface thereof, and through-vias electrically connecting the first connection pads to a first subset of the second connection pads,
wherein each of the memory dies comprises third connection pads at an upper surface thereof and in contact with a second subset of the second connection pads,
wherein the mold vias are in contact with the first connection pads, and
wherein a first thickness of the logic die is different from a second thickness of each of the memory dies in a direction that is perpendicular to the upper surface of the logic die.

18. The semiconductor package of claim 17,
wherein each of the memory dies comprises memory bank regions arranged side by side in a second direction intersecting the first direction, and
wherein the logic die comprises core regions overlapping the memory bank regions, respectively, in a third direction that is perpendicular to the first and second directions.

19. The semiconductor package of claim 17,
wherein the logic die further comprises a peripheral circuit region overlapping the second mold layer, and
wherein the peripheral circuit region comprises column decoder circuits, row decoder circuits, an input/output circuit, a voltage generation circuit, and a fuse circuit.

20. The semiconductor package of claim 17, wherein each of the memory dies further comprises:
active patterns extending perpendicular to the upper surface of the logic die;
word lines extending alongside the active patterns;
bit lines arranged under the active patterns; and
data storage elements on the active patterns opposite the bit lines.
